(19) United States
(12) Patent Application Publication
(10) Pub. No.: US 2026/0330104 A1
(43) Pub. Date: Oct. 22, 2026

(54) LLM-BASED CHIP SELECTION METHOD AND FRAMEWORK, AND CIRCUIT DESIGN METHOD

(71) Applicant: Hangzhou Shi Wei Xin Tu Technology Co., Ltd, Hangzhou (CN)

(72) Inventors: Gang FANG, Hangzhou (CN); Zhenxin ZHAO, Hangzhou (CN); Zihan XU, Hangzhou (CN); Wei DONG, Hangzhou (CN)

(73) Assignee: Hangzhou Shi Wei Xin Tu Technology Co., Ltd, Hangzhou (CN)

(21) Appl. No.: 19/646,643

(22) Filed: Apr. 14, 2026

(30) Foreign Application Priority Data
Apr. 18, 2025 (CN) 202510487704.4

(51) Int. Cl. G06F 30/27

(52) U.S. Cl. CPC G06F 30/27

(57) ABSTRACT

A large language model (LLM)-based chip selection method and framework, and a circuit design method are provided. The LLM-based chip selection method includes: SA1, acquiring to-be-processed interactive information; SA2, performing information extraction on the to-be-processed interactive information, and obtaining initial requirement information; SA3, analyzing whether the initial requirement information contains an abnormal requirement; SA4, if the initial requirement information contains the abnormal requirement, feeding the abnormal requirement and a cause of the abnormal requirement back to a user, and interacting with the user to re-generate interactive information, to perform the SA2 based on newly generated interactive information; and SA5, if the initial requirement information does not contain the abnormal requirement, performing requirement analysis and standardization processing based on the initial requirement information, thereby obtaining, based on the initial requirement information, chip product requirement information whose data item name at least includes product classification, and outputting the chip product requirement information.

### CROSS REFERENCE TO THE RELATED APPLICATIONS

This application is based upon and claims priority to Chinese Patent Application No. 202510487704.4, filed on Apr. 18, 2025, the entire contents of which are incorporated herein by reference.

### TECHNICAL FIELD

The present disclosure relates to the field of computers, and in particular, to a large language model (LLM)-based chip selection method and framework, and a circuit design method.

### BACKGROUND

With the rapid development of artificial intelligence (AI) technologies, large language models (LLMs) demonstrate significant potential across a plurality of fields. In the field of chip design, LLMs can provide assistance in a plurality of stages of an automated chip design process through natural language processing and generation technologies, thereby enhancing design efficiency and quality.

In the automated chip design process, an LLM is first used for interaction to collect chip product requirements from users. However, due to a lack of corresponding design, on one hand, it is difficult for technical personnel to express these requirements in a standardized and accurate manner. As a result, described content, regardless of its length, has a problem of poor directivity or pertinence, leading to unsatisfactory accuracy of a conclusion output by the LLM. On the other hand, the chip product requirements provided by the front end usually have problems such as uncertainty, vague presentation, and lack of key weight information, which lead to non-standardization of information transmission and lack of key information during further information processing, thereby further affecting the accuracy of the conclusion output by the LLM.

### SUMMARY

To address the deficiencies in the prior art, the present disclosure provides an LLM-based chip selection method and framework, and a circuit design method, which solve a problem that existing LLM-driven automated chip design has defects in an interaction function and thus reduces accuracy of a conclusion output by an LLM.

According to embodiments of the present disclosure, a first aspect provides an LLM-based chip selection method, including:
SA1, acquiring to-be-processed interactive information, where the to-be-processed interactive information is all interactive information generated during chip selection in a human-machine collaborative mode;
SA2, performing information extraction on the to-be-processed interactive information, and obtaining initial requirement information;
SA3, analyzing whether the initial requirement information contains an abnormal requirement, where the abnormal requirement indicates that the initial requirement information has at least one of an unreasonable requirement expression, an ambiguous expression, and an irrelevant expression;
SA4, if the initial requirement information contains the abnormal requirement, feeding the abnormal requirement and a cause of the abnormal requirement back to a user, and interacting with the user to re-generate interactive information, so as to perform the SA2 based on the newly generated interactive information; and
SA5, if the initial requirement information does not contain the abnormal requirement, performing requirement analysis and standardization processing based on the initial requirement information, thereby obtaining, based on the initial requirement information, chip product requirement information whose data item name at least includes product classification, and outputting the chip product requirement information; where
supervised fine-tuning training is performed on a first basic agent by using a first hybrid dataset including a proper noun dataset, a product classification dataset, a multi-turn dialogue dataset, and a general dataset, and an interactive agent is obtained to perform the SA1 to SA5.

Optionally, the proper noun dataset includes K noun data contents based on K proper nouns; and
a k^{th} noun data content includes a proper noun question-answer (QA) pair constituted by a correct interpretation of a k^{th} proper noun and a question sentence based on the correct interpretation of the k^{th} proper noun, and a system prompt based on the proper noun QA pair, where k is a positive integer less than or equal to K, and K is a positive integer.

Optionally, the product classification dataset includes N category data contents based on M first-level chip categories; and
if an n^{th} category data content belongs to an m^{th} first-level chip category, the n^{th} category data content includes a product classification QA pair constituted by a second-level chip category subordinate to the m^{th} first-level chip category and a question sentence based on the second-level chip category subordinate to the m^{th} first-level chip category, and a system prompt based on the product classification QA pair, where
M and N are positive integers, n is a positive integer less than or equal to N, and m is a positive integer less than or equal to M.

Optionally, the multi-turn dialogue dataset includes U multi-turn dialogue data contents based on L multi-turn dialogues; and
if a u^{th} multi-turn dialogue data content belongs to an l^{th} multi-turn dialogue, the u^{th} multi-turn dialogue data content includes a multi-turn dialogue QA pair constituted by a simulated question in the l^{th} multi-turn dialogue and a reply content based on the simulated question in the l^{th} multi-turn dialogue, a system prompt based on the multi-turn dialogue QA pair, and a historical dialogue set, where
L and U are positive integers, l is a positive integer less than or equal to L, and u is a positive integer less than or equal to U; in the l^{th} multi-turn dialogue, the simulated question is generated by simulating a user question about a randomly selected chip product manual; and the reply content based on the simulated question in the l^{th} multi-turn dialogue is generated based on the randomly selected chip product manual.

Optionally, in the l^{th} multi-turn dialogue, the simulated question is also randomly selected from a preset question database; and for the simulated question randomly selected from the preset question database, the reply content of the simulated question includes content of the randomly selected chip product manual; and
the preset question database includes a plurality of preset questions, and each of the preset questions includes at least one of the unreasonable requirement expression, the ambiguous expression, and the irrelevant expression.

A second aspect provides an LLM-based chip selection method, including:
SB1, acquiring chip product requirement information provided by an interactive agent, where the interactive agent executes the above LLM-based chip selection method;
SB2, performing, by a selection agent as a generation module, chip selection based on the chip product requirement information by combining a pre-configured retrieval module, reranking module, and local knowledge base, and outputting chip recommendation information, where
the SB2 includes:
comparing the chip product requirement information with chip product data stored in the local knowledge base by using the retrieval module, obtaining a plurality of relevant documents, and sending the plurality of relevant documents to the reranking module;
performing relevance ranking on the plurality of relevant documents by using the reranking module, and sending a ranking result to the selection agent, where in the ranking result, a relevant document with higher relevance is assigned a smaller serial number, and a relevant document whose serial number is smaller than a preset serial number is a strongly-related document; and
analyzing all strongly-related documents based on the chip product requirement information, and outputting the chip recommendation information.

Optionally, the LLM-based chip selection method includes constructing a retrieval triplet dataset to perform supervised contrastive learning training on a foundation embedding model, and obtaining the retrieval module upon completion of the training; where
the constructed retrieval triplet dataset includes a query retrieval element, a positive-sample retrieval element, and a negative-sample retrieval element; the query retrieval element is extracted from total requirement information data; the positive-sample retrieval element is unique chip product data selected from the local knowledge base to reply to the query retrieval element; and the negative-sample retrieval element is a plurality of pieces of chip product data randomly extracted from the local knowledge base.

Optionally, the LLM-based chip selection method includes constructing a reranking triplet dataset to perform supervised contrastive learning training on a basic reranking model, and obtaining the reranking module upon completion of the training; where
the constructed reranking triplet dataset includes a query reranking element, a positive-sample reranking element, and a negative-sample reranking element; the query reranking element is a simulated requirement description whose data size is less than a preset quantity of bytes; the positive-sample reranking element is a unique correct answer compiled based on the simulated requirement description; and the negative-sample reranking element is a plurality of wrong answers compiled based on the simulated requirement description, where a similarity between each of the wrong answers and the unique correct answer is greater than a preset similarity.

Optionally, any piece of chip product data stored in the local knowledge base includes a document description of a product feature, a document description of a product application case, a document description of a key parameter, and a document description of complete information.

Optionally, the LLM-based chip selection method includes performing two-stage training including continued pre-training and supervised fine-tuning training on a second basic agent, and obtaining the selection agent to perform the SB1 and SB2;
in the continued pre-training, multi-dimensional chip text data is obtained, text preprocessing is performed on the multi-dimensional chip text data to obtain a plurality of corpus blocks, and the second basic agent is trained by using the plurality of corpus blocks; and
in the supervised fine-tuning training, the second basic agent after the continued pre-training is trained by using a second hybrid dataset including a proper noun dataset, a product classification dataset, a chip selection dataset, and a general dataset, and the selection agent is obtained.

Optionally, the chip selection dataset includes P pieces of chip matching data; and
a p^{th} piece of chip matching data includes a chip matching QA pair constituted by a simulated chip requirement description and recommendation information meeting the simulated chip requirement description, and a system prompt based on the chip matching QA pair, where
the simulated chip requirement description is generated based on a randomly selected chip product manual; and
the recommendation information meeting the simulated chip requirement description includes a chip product model and a chip product description that are recorded in the randomly selected chip product manual.

A third aspect provides an LLM-based chip selection framework, including an LLM-driven interactive agent, selection agent, and evaluation agent, where the interactive agent executes the LLM-based chip selection method in the first aspect; the selection agent executes the LLM-based chip selection method in the second aspect; and the evaluation agent performs following steps:
SC1, acquiring chip recommendation information, where
the chip recommendation information is a result of performing, by the selection agent as a generation module, chip selection based on chip product requirement information by combining a pre-configured retrieval module, reranking module, and local knowledge base;
SC2, performing confidence evaluation on the chip recommendation information; and
SC3, if a confidence level obtained according to the SC2 is a highest level, sending the chip recommendation information to a user. Optionally, in the SC2, when the confidence evaluation is performed on the chip recommendation information, evaluation content is also generated.

Optionally, a following step is further included:
SC4, if the confidence level obtained according to the SC2 is not the highest level, sending evaluation content corresponding to the confidence level obtained according to the SC2 to the selection agent, such that the selection agent modifies the chip recommendation information.

Optionally, the evaluation agent is designed through prompt engineering, and the SC1 to the SC3 are performed by the evaluation agent.

A fourth aspect provides a circuit design method, including:
SD1, acquiring a circuit design request, where the circuit design request includes interactive information that at least describes one circuit module, and different circuit modules have different interactive information;
SD2, decomposing the circuit design request into a plurality of circuit module design tasks and an execution order of the plurality of circuit module design tasks;
SD3, when executing a target circuit module design task, calling the above chip selection framework, where the chip selection framework is configured to perform requirement analysis based on the circuit design request to obtain chip product requirement information, perform chip selection based on the chip product requirement information to obtain chip recommendation information, and perform confidence evaluation on the chip recommendation information;
SD4, when a confidence level of the chip recommendation information is a highest level, obtaining a target chip based on the chip recommendation information, and building a simulation circuit or a test circuit by using the target chip based on a requirement of the target circuit module design task to perform verification;
SD5, when the verification is successful, taking the target chip as a chip for executing the target circuit module design task; and
SD6, executing each of the circuit module design tasks according to the SD3 to the SD5 to complete circuit design.

A fifth aspect provides an electronic device, including a memory, a processor, and a computer program stored on the memory and executable on the processor, where the processor executes the computer program to implement the LLM-based chip selection method described in the first aspect, the LLM-based selection chip method described in the second aspect, or the above circuit design method.

A sixth aspect provides a computer-readable storage medium, storing a computer program thereon, where the computer program is executed by a processor to implement the LLM-based chip selection method described in the first aspect, the LLM-based chip selection method described in the second aspect, or the above circuit design method.

A seventh aspect provides a computer program product, including a computer program, where the computer program is executed by a processor to implement the LLM-based chip selection method described in the first aspect, the LLM-based chip selection method described in the second aspect, or the above circuit design method.

The LLM-based chip selection method provided in the present disclosure continuously interacts with a user in a human-machine collaborative mode to guide the user in chip selection, performs information extraction on to-be-processed interactive information, and thereby collects the user's chip product requirement, namely initial requirement information. It also analyzes the initial requirement information to prevent an abnormal requirement such as an unreasonable requirement expression, an ambiguous expression, or an irrelevant expression from affecting subsequent information processing, thus ensuring usability of output chip product requirement information. In addition, the LLM-based chip selection method performs standardization processing on the initial requirement information to enhance directivity of the output chip product requirement information, and ultimately improves accuracy of a conclusion output by an LLM.

### BRIEF DESCRIPTION OF THE DRAWINGS

FIG. 1 is a schematic flowchart of implementing an LLM-based chip selection method according to an embodiment of the present disclosure;

FIG. 2 is a schematic flowchart of implementing another LLM-based chip selection method according to an embodiment of the present disclosure;

FIG. 3 is a schematic diagram of a composition structure of an LLM-based chip selection framework according to an embodiment of the present disclosure;

FIG. 4 shows execution steps to be performed by an evaluation agent according to an embodiment of the present disclosure;

FIG. 5 is a schematic flowchart of implementing a circuit system design method according to an embodiment of the present disclosure; and

FIG. 6 is a schematic structural diagram of an electronic device according to an embodiment of the present disclosure.

### DETAILED DESCRIPTION OF THE EMBODIMENTS

The following further describes the technical solutions of the present disclosure in detail with reference to the accompanying drawings and embodiments.

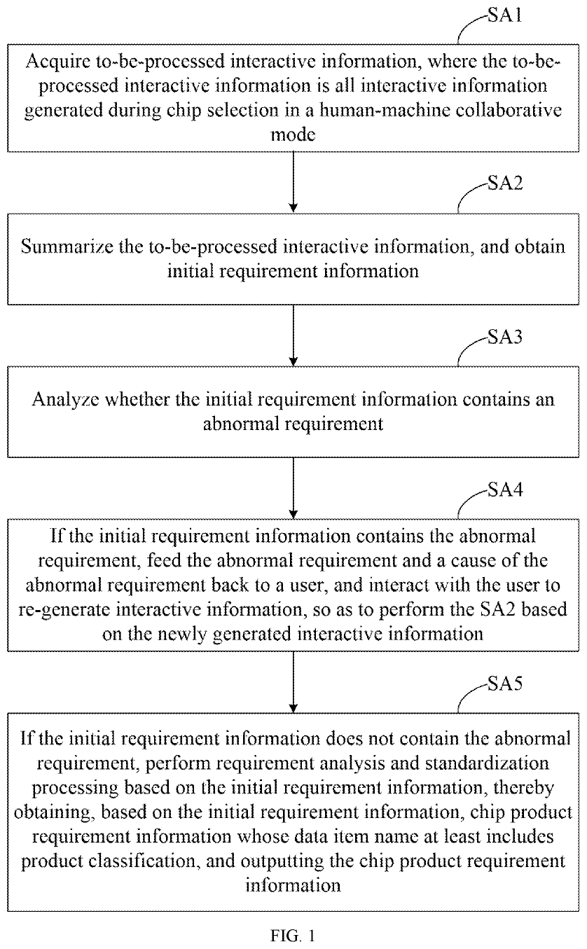

As shown in FIG. 1, the embodiments of the present disclosure provide an LLM-based chip selection method. The LLM-based chip selection method enables a currently controlled agent, namely an interactive agent, to continuously interact with a user, acquire a chip product requirement of the user, and perform information extraction. Meanwhile, the LLM-based chip selection method provides a function of identifying an abnormal requirement to ensure usability of output chip product requirement information.

The LLM-based chip selection method includes but is not limited to the following steps:
SA1: To-be-processed interactive information is obtained, where the to-be-processed interactive information is all interactive information generated during chip selection in a human-machine collaborative mode.
SA2: The information extraction is performed on the to-be-processed interactive information, and initial requirement information is obtained.
SA3: Whether the initial requirement information contains an abnormal requirement is analyzed, where the abnormal requirement indicates that the initial requirement information has at least one of an unreasonable requirement expression, an ambiguous expression, and an irrelevant expression.
SA4: If the initial requirement information contains the abnormal requirement, the abnormal requirement and a cause of the abnormal requirement are fed back to the user, and interactive information is re-generated through interaction with the user, so as to perform the SA2 based on the newly generated interactive information.

SA5: If the initial requirement information does not contain the abnormal requirement, requirement analysis and standardization processing are performed based on the initial requirement information, thereby obtaining, based on the initial requirement information, chip product requirement information whose data item name at least includes product classification, and outputting the chip product requirement information.

In the step SA1, in the human-machine collaborative mode, the interactive agent in the embodiments of the present disclosure guides the user in the chip selection. A detailed process may be as follows: The user conducts a plurality of rounds of interaction with the interactive agent to provide chip selection-related information in voice, text, and other forms, including but not limited to a chip model, a chip parameter, a chip function, and the like. Based on this, the to-be-processed interactive information includes, but is not limited to, voice information, text information, and the like provided by the user.

For the steps SA2, SA3, and SA5, the embodiments of the present disclosure provide a specific dataset to train the interactive agent, enabling the interactive agent to perform the information extraction on the to-be-processed interactive information, identify the abnormal requirement, and perform the requirement analysis and the data standardization processing on the initial requirement information that does not contain the abnormal requirement.

For the step SA3, the abnormal requirement analyzed in the step SA3 indicates that the initial requirement information contains the unreasonable requirement expression, the ambiguous expression, the irrelevant expression, and the like. In a specific application, the abnormal requirement affects the chip product requirement information output in the step SA5, and as a result, a selection agent fails to perform the chip selection or a chip selection result is inaccurate.

For the step SA5, the chip product requirement information output in the step SA5 is finally sent to the selection agent. The chip product requirement information is standardized data whose data item name at least includes product classification. For example, the data item name includes a first-level product category, a second-level product category, a product application, and a key product parameter.

In the embodiments of the present disclosure, a basic agent is trained prior to the step SA1 to obtain the interactive agent capable of implementing the functions shown in the steps SA1 to SA5. Specifically, supervised fine-tuning training is performed on a first basic agent by using a first hybrid dataset including a proper noun dataset, a product classification dataset, a multi-turn dialogue dataset, and a general dataset.

It should be noted that the proper noun dataset and the product classification dataset herein are used to enable the interactive agent to better understand and solve problems in the field of electronic information, especially to have a capability to select a suitable chip product for each circuit module in board-level circuit design. The multi-turn dialogue dataset is used to enable the interactive agent to continuously interact with the user without deviating from the field of electronic information.

In the embodiments of the present disclosure, the proper noun dataset includes K noun data contents based on K proper nouns, where the K proper nouns all belong to the field of electronic information. For example, a k^{th} noun data content includes a proper noun QA pair constituted by a correct interpretation of a k^{th} proper noun and a question sentence based on the correct interpretation of the k^{th} proper noun, and a system prompt based on the proper noun QA pair.

The system prompt based on the proper noun QA pair is used to instruct the interactive agent to perform the information extraction on the to-be-processed interactive information in accordance with an exemplified correspondence rule between a correct interpretation of a proper noun in the proper noun dataset and a question sentence based on the correct interpretation of the proper noun.

In a specific application, the correct interpretation of the k^{th} proper noun is represented by Aᵢ|_{proper noun}, and a question sentence based on a correct interpretation of any proper noun, namely Aᵢ|_{proper noun}, is represented by Qᵢ|_{proper noun}. Therefore, the Aᵢ|_{proper noun} and the Qᵢ|_{proper noun} form a “QA” pair, namely the proper noun QA pair. Then, the system prompt based on the proper noun QA pair is represented by S|_{proper noun}. Based on this, the proper noun dataset in the embodiments of the present disclosure can be expressed as follows:

$${D}_{proper noun} = {\{ {Q}_{i} {\vert}_{proper noun} , {A}_{i} {\vert}_{proper noun} , S {\vert}_{proper noun} \}}_{i = 1}^{{N}_{proper noun}}$$

Where, N_{proper noun} represents a quantity of data items in the proper noun dataset D_{proper noun}, and N_{proper noun}=K.

In the embodiments of the present disclosure, the product classification dataset includes N category data contents based on M first-level chip categories. For example, if an n^{th} category data content belongs to an m^{th} first-level chip category, the n^{th} category data content includes a product classification QA pair constituted by a second-level chip category subordinate to the m^{th} first-level chip category and a question sentence based on the second-level chip category subordinate to the m^{th} first-level chip category, and a system prompt based on the product classification QA pair. The system prompt based on the product classification QA pair is used to instruct the interactive agent to classify a first-level chip category and a second-level chip category subordinate to the first-level category based on the initial requirement information and in accordance with an exemplified correspondence rule between the second-level chip category of the m^{th} first-level chip category and the question sentence based on the second-level chip category of the m^{th} first-level chip category in the product classification dataset.

It should be noted that in the product classification dataset, the N category data contents are divided into the M first-level chip categories for storage. In an embodiment, 16 first-level chip categories are provided, namely amplifiers, audio devices, battery management integrated circuits (BMICs), clock and timing devices, data converters, digital light processing (DLP) products, interfaces, isolators, logic and voltage conversion devices, microcontrollers and processors, motor drivers, power management devices, radio frequency (RF) and microwave devices, sensors, switches and multiplexers, and wireless connectors. Then, the M first-level chip categories are classified to obtain second-level chip categories, where there is a subordinate relationship between a second-level chip category and a first-level chip category. Each first-level chip category includes a plurality of category data contents based on its second-level chip categories. For example, the sensors, as a first-level chip category, include a photoelectric sensor, an infrared sensor, and the like. Therefore, the photoelectric sensor and the infrared sensor are category data contents of a corresponding second-level chip category. For a single category data content in the product classification dataset, assuming that this category data content represents the photoelectric sensor, this category data content includes a product classification QA pair constituted by the photoelectric sensor (second-level chip category) subordinate to the sensors (first-level chip category) and a question sentence based on the photoelectric sensor (second-level chip category) subordinate to the sensors (first-level chip category), and a system prompt based on the product classification QA pair.

In a specific application, the relationship between the first-level chip category and the second-level chip category is represented by Aᵢ|_{product classification}, indicating that the second-level chip category belongs to the m^{th} first-level chip category. For each Aᵢ|_{product classification}, question sentence Qᵢ|_{product classification} is designed. Therefore, the Aᵢ|_{product classification} and the Qᵢ|_{product classification} form a “QA” pair, namely, the product classification QA pair. Then, the system prompt based on the product classification QA pair is represented by S|_{product classification}. Based on this, the product classification dataset in the embodiments of the present disclosure can be expressed as follows:

$${{D}_{product classification} = {Q}_{i} {\vert}_{product classification} , {A}_{i} {\vert}_{product classification} , S {\vert}_{product classification} \}}_{i = 1}^{{N}_{product classification}}$$

Where, N_{product classification} represents a quantity of data items in the product classification dataset D_{product classification}, and N_{product classification}=N.

In the embodiments of the present disclosure, the multi-turn dialogue dataset includes U multi-turn dialogue data contents based on L multi-turn dialogues. For example, if a u^{th} multi-turn dialogue data content belongs to an l^{th} multi-turn dialogue, the u^{th} multi-turn dialogue data content includes a multi-turn dialogue QA pair constituted by a simulated question in the l^{th} multi-turn dialogue and a reply content based on the simulated question in the l^{th} multi-turn dialogue, a system prompt based on the multi-turn dialogue QA pair, and a historical dialogue set.

The above simulates how the user asks a question about the chip product manual. For example, in the l^{th} multi-turn dialogue, the simulated question is generated by simulating a user question about a randomly selected chip product manual; and the reply content based on the simulated question in the l^{th} multi-turn dialogue is generated based on the randomly selected chip product manual. In addition, the interactive agent in the embodiments of the present disclosure also analyzes the abnormal requirement. Therefore, in the l^{th} multi-turn dialogue, the simulated question is also randomly selected from a preset question database; and for the simulated question randomly selected from the preset question database, the reply content of the simulated question includes content of the randomly selected chip product manual. The preset question database includes a plurality of preset questions, and each of the preset questions includes at least one of the unreasonable requirement expression, the ambiguous expression, and the irrelevant expression.

In a specific application, the simulated question in the l^{th} multi-turn dialogue is represented by Qᵢ|_{multi-turn dialogue}, and the reply content based on the Qᵢ|_{multi-turn dialogue} is represented by Aᵢ|_{multi-turn dialogue}. Then, the Qᵢ|_{multi-turn dialogue} and the Aᵢ|_{multi-turn dialogue} form a “QA” pair, namely the multi-turn dialogue QA pair. Next, the system prompt based on the multi-turn dialogue QA pair is represented by S|_{multi-turn dialogue} In addition, the historical dialogue set Hᵢ|_{multi-turn dialogue} is also used to provide assistance in the training. Based on this, the multi-turn dialogue dataset in the embodiments of the present disclosure can be expressed as follows:

$${D}_{multi - turn dialogue} = {\{ {Q}_{i} {\vert}_{multi - turn dialogue} , {A}_{i} {\vert}_{multi - turn dialogue} , S {\vert}_{multi - turn dialogue} \}}_{i = 1}^{{N}_{multi - turn dialogue}}$$

Where, N_{multi-turn dialogue} represents a quantity of data items in the multi-turn dialogue dataset D_{multi-turn dialogue}, and N_{multi-turn dialogue}=U.

It should be noted that in the embodiments of the present disclosure, the multi-turn dialogue dataset actually includes a dataset constructed based on the questioning idea of the natural person regarding the chip product manual, as well as a dataset constructed based on an idea of the natural person raising the abnormal requirement, that is, based on the preset question database. Therefore, the system prompt based on the multi-turn dialogue QA pair is used to instruct the interactive agent to analyze the abnormal requirement in the initial requirement information in accordance with an exemplified corresponding rule between the simulated question and the reply content based on the simulated question in the multi-turn dialogue dataset, and provide guidance when the initial requirement information includes the abnormal requirement, that is, interact with the user to re-generate the interactive information, so as to supplement or correct the previous abnormal requirement based on the newly generated interactive information.

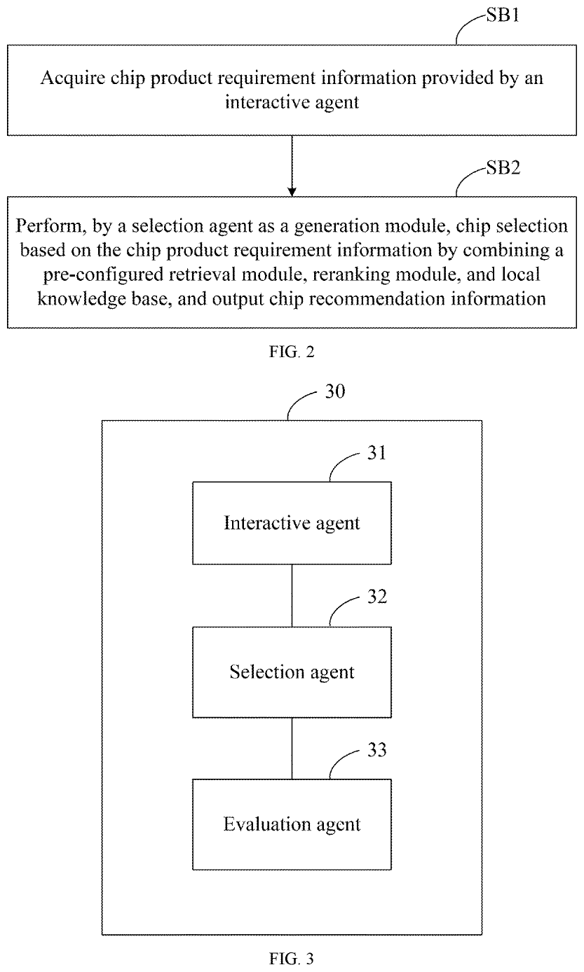

As shown in FIG. 2, the embodiments of the present disclosure further provide an LLM-based chip selection method. After the chip product requirement information is output to the selection agent in the SA5 in the above embodiments, a currently controlled agent, namely the selection agent, performs chip selection based on the chip product requirement information and outputs chip recommendation information. In addition, a retrieval augmentation technology is provided to improve a chip selection capability of the selection agent. This is different from a scheme in existing board-level circuit design, where a recommendation is automatically made based on market value, a user selection rate, and the like, and if there are a plurality of similar chip products, a user is prompted to make a choice independently. The LLM-based chip selection method shown in FIG. 2 includes but is not limited to the following steps:
SB1: The chip product requirement information provided by an interactive agent is acquired, where the interactive agent executes the above LLM-based chip selection method.
SB2: The selection agent, as a generation module, performs chip selection based on the chip product requirement information by combining a pre-configured retrieval module, reranking module, and local knowledge base, and the chip recommendation information is output.

The SB2 includes the following steps:

The chip product requirement information is compared with chip product data stored in the local knowledge base by using the retrieval module, and a plurality of relevant documents are obtained and sent to the reranking module.

Relevance ranking is performed on the plurality of relevant documents by using the reranking module, and a ranking result is sent to the selection agent, where in the ranking result, a relevant document with higher relevance is assigned a smaller serial number, and a relevant document whose serial number is smaller than a preset serial number is a strongly-related document.

All strongly-related documents are analyzed based on the chip product requirement information, and the chip recommendation information is output.

The chip product requirement information in the step SB1 is provided by the interactive agent. Specifically, the interactive agent performs chip selection with the user based on the LLM-based chip selection method shown in FIG. 1, then generates to-be-processed interactive information through continuous interaction during the chip selection, and finally performs information extraction and requirement analysis based on the to-be-processed interactive information to obtain the chip product requirement information.

Both the step SB1 and the step SB2 are executed by the selection agent. According to the step SB2, the embodiments of the present disclosure provide the LLM-based chip selection method, which not only performs the chip selection through the selection agent, but also designs the retrieval augmentation technology by using the selection agent as the generation module, thereby integrating an LLM and retrieval-augmented generation. Through this approach, a selection capability of the chip selection is improved, and in the case of a plurality of similar chip products, an optimal solution can also be output.

In the embodiments of the present disclosure, the retrieval module, the reranking module, the local knowledge base, and the selection agent are described in detail.

Firstly, for the retrieval module, in an embodiment, a retrieval triplet dataset is constructed to perform supervised contrastive learning training on a foundation embedding model, and the retrieval module is obtained upon completion of the training. In a specific application, the triplet dataset contains three elements: query Q, positive sample P, and negative sample N. Herein, the Q represents an input question, the P represents a correct answer or a standard answer, and the N represents a negative incorrect answer. In a preferred implementation, the retrieval triplet dataset constructed in the embodiments of the present disclosure includes a query retrieval element, a positive-sample retrieval element, and a negative-sample retrieval element. The query retrieval element is extracted from total requirement information data; the positive-sample retrieval element is unique chip product data selected from the local knowledge base to reply to the query retrieval element; and the negative-sample retrieval element is a plurality of pieces of chip product data randomly extracted from the local knowledge base. It should be noted that the total requirement information data is all requirement information output by the interactive agent within a historical time period, which is herein used as a data source for the query retrieval element in the retrieval triplet dataset.

In a specific application, the query retrieval element is represented by Qᵢ|_{embedding}, the positive-sample retrieval element is represented by Pᵢ|_{embedding}, and the negative-sample retrieval element is represented by Nᵢ|_{embedding}. Based on this, the retrieval triplet dataset in the embodiments of the present disclosure can be expressed as follows:

$${T}_{embedding} = {\{ {Q}_{i} {\vert}_{embedding} , {A}_{i} {\vert}_{embedding} , S {\vert}_{embedding} \}}_{i = 1}^{{N}_{embedding}}$$

Where, N_{embedding} represents a quantity of data items in the triplet dataset T_{embedding}.

Secondly, for the reranking module, in an embodiment, a reranking triplet dataset is constructed to perform supervised contrastive learning training on a basic reranking model, and the reranking module is obtained upon completion of the training. In a specific application, the triplet dataset contains three elements: query Q, positive sample P, and negative sample N. Herein, the Q represents an input question, the P represents a correct answer or a standard answer, and the N represents a negative incorrect answer. In a preferred implementation, the reranking triplet dataset constructed in the embodiments of the present disclosure, which is more concise and refined than the aforementioned retrieval triplet dataset, includes a query reranking element, a positive-sample reranking element, and a negative-sample reranking element. The query reranking element is a simulated requirement description whose data size is less than a preset quantity of bytes; the positive-sample reranking element is a unique correct answer compiled based on the simulated requirement description; and the negative-sample reranking element is a plurality of wrong answers compiled based on the simulated requirement description, where a similarity between the wrong answer and the unique correct answer is greater than a preset value. It should be noted that a constraint of setting data size of the simulated requirement description to be less than the preset quantity of bytes is used to indicate that the reranking triplet dataset is more concise and refined than the previous retrieval triplet dataset used for training the foundation embedding model. A constraint of setting the similarity between the incorrect answer and the unique correct answer to be greater than the preset value is used to enhance performance of the reranking model, enabling the reranking model to more accurately distinguish between strongly-related and weakly-related relevant documents, which is beneficial for the selection agent to find the optimal solution in the case of the plurality of similar chip products.

In a specific application, the query reranking element is represented by Qᵢ|_{reranking}, the positive-sample reranking element is represented by Pᵢ|_{reranking}, and the negative-sample reranking element is represented by Nᵢ|_{reranking}. Based on this, the reranking triplet dataset in the embodiments of the present disclosure can be expressed as follows:

$${T}_{reranking} = {\{ {Q}_{i} {\vert}_{reranking} , {A}_{i} {\vert}_{reranking} , S {\vert}_{reranking} \}}_{i = 1}^{{N}_{reranking}}$$

Where, N_{reranking} represents a quantity of data items in the reranking triplet dataset T_{reranking}.

In an embodiment, any piece of chip product data stored in the local knowledge base includes a document description of a product feature, a document description of a product application case, a document description of a key parameter, and a document description of complete information. In a specific application, the chip product data can be obtained by extracting information from a plurality of chip product manuals, and then stored in the local knowledge base. A new chip product manual can also be acquired regularly to extract information based on the new chip product manual to obtain new chip product data, and then the local knowledge base is updated.

Finally, in an embodiment, a second basic agent is trained to obtain the LLM-based chip selection method shown in FIG. 2, especially the selection agent in the step SB2. Detailed implementation steps are as follows:

Two-stage training including continued pre-training and supervised fine-tuning training is performed on the second basic agent, the selection agent is obtained to analyze all the strongly-related documents based on the chip product requirement information, and the chip recommendation information is output.

In the continued pre-training, multi-dimensional chip text data is obtained, text preprocessing is performed on the multi-dimensional chip text data to obtain a plurality of corpus blocks, and the second basic agent is trained by using the plurality of corpus blocks.

In the supervised fine-tuning training, the second basic agent after the continued pre-training is trained by using a second hybrid dataset including a proper noun dataset, a product classification dataset, a chip selection dataset, and a general dataset, and the selection agent is obtained.

It should be noted that the multi-dimensional chip text data includes, but is not limited to, books related to electronic science and technology, industry standard documents, research reports, web forums, publicly available guidelines from well-known industry companies, and the like. Text preprocessing methods include, but are not limited to, text content extraction, regular expression refinement, noise reduction optimization, manual refinement, and the like. The continued pre-training based on the multi-dimensional chip text data is intended to enable the selection agent to better understand and solve problems in the field of electronic information. The proper noun dataset and the product classification dataset used herein contain same data contents as those contained in the first hybrid dataset. The chip selection dataset is used to train the chip selection capability of the selection agent, that is, to find a chip product that matches target requirement information.

Different from the chip selection dataset in the first hybrid dataset, the chip selection dataset in the second hybrid dataset includes P pieces of chip matching data. For example, a p^{th} piece of chip matching data includes a chip matching QA pair constituted by a preset chip requirement description and recommendation information that meets the preset chip requirement description, and a system prompt based on the chip matching QA pair. The preset chip requirement description is generated based on the randomly selected chip product manual; and the recommendation information that meets the preset chip requirement description is a chip product model and a chip product description that are recorded in the randomly selected chip product manual.

In a specific application, the preset chip requirement description is represented by Qᵢ|_{chip selection}, the recommendation information that meets the Qᵢ|_{chip selection} is represented by Aᵢ|_{chip selection}. Therefore, the Qᵢ|_{chip selection} and the Aᵢ|_{chip selection} form the chip matching QA pair. Then the system prompt based on the chip matching QA pair is represented by the S|_{chip selection}. Based on this, the chip selection dataset in the embodiments of the present disclosure can be expressed as follows:

$${D}_{chip selection} = {\{ {Q}_{i} {\vert}_{chip selection} , {A}_{i} {\vert}_{chip selection} , S {\vert}_{chip selection} \}}_{i = 1}^{{N}_{chip selection}}$$

Where, N_{chip selection} represents a quantity of data items in the chip selection dataset D_{chip selection}, and D_{chip selection}=P.

Therefore, the system prompt based on the chip matching QA pair is used to instruct the selection agent to perform the chip selection based on the chip product requirement information and in accordance with an exemplified corresponding rule between the preset chip requirement description and the recommendation information that meets the preset chip requirement description in the chip matching data in the multi-turn dialogue dataset, and output the chip recommendation information.

As shown in FIG. 3, the embodiments of the present disclosure provide LLM-based chip selection framework 30, including LLM-driven interactive agent 31, selection agent 32, and evaluation agent 33. The interactive agent 31 executes the LLM-based chip selection method shown in FIG. 1, and the selection agent 32 executes the LLM-based chip selection method shown in FIG. 2.

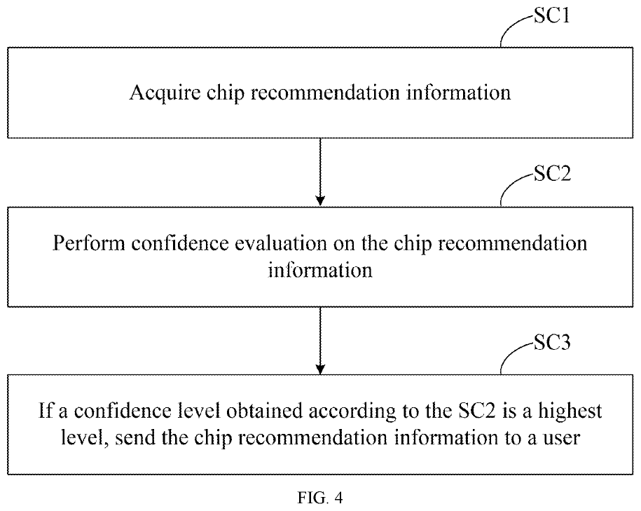

As shown in FIG. 4, the evaluation agent 33 performs the following steps to compare requirement information output by the interactive agent with recommendation information output by the selection agent, in order to determine whether chip selection made by the selection agent based on target requirement information and chip recommendation information that is based on a target chip and output to the evaluation agent satisfy requirements of the interactive agent, and provide an evaluated confidence level and a basis:

SC1: The chip recommendation information is acquired.

The chip recommendation information is a result of performing, by the selection agent as a generation module, the chip selection based on chip product requirement information by combining a pre-configured retrieval module, reranking module, and local knowledge base.

SC2: Confidence evaluation is performed on the chip recommendation information.

SC3: If a confidence level obtained according to the SC2 is a highest level, the chip recommendation information is sent to a user.

For the step SC2, in the embodiments of the present disclosure, when the confidence evaluation is performed on the chip recommendation information based on the target chip, evaluation content is also generated. Based on this, after the confidence evaluation is performed on the chip recommendation information in the step SC2, the confidence level and the evaluation content are generated. For example, confidence levels are ranked in a descending order, including:

full requirement satisfaction>partial requirement satisfaction>minimal requirement satisfaction>requirement dissatisfaction.

For example, evaluation content corresponding to the full requirement satisfaction is that the recommendation information based on the target chip fully satisfies the target requirement information. Evaluation content corresponding to the partial requirement satisfaction is that the recommendation information based on the target chip partially satisfies the target requirement information. Evaluation content corresponding to the minimal requirement satisfaction is that only a small portion of the recommendation information based on the target chip satisfies the user's requirement. Evaluation content corresponding to the requirement dissatisfaction is that the recommendation information based on the target chip does not meet the user's requirement at all or the selection agent generates irrelevant content.

In another embodiment of the present disclosure, based on the steps SC1 to SC3 executed by the evaluation agent 33 shown in FIG. 4, a processing method adopted when the confidence level is not the highest level is also provided, including the following step:

SC4: If the confidence level obtained according to the SC2 is not the highest level, evaluation content corresponding to the confidence level obtained according to the SC2 is sent to the selection agent, such that the selection agent modifies the chip recommendation information.

It should be noted that for the selection agent, the LLM-based chip selection method shown in FIG. 2 may also include the following step:

SB3: If generated evaluation content corresponding to a current confidence level that is not the highest level is received, a chip selection result in the SB2 is modified, and modified chip recommendation information is output.

Through the above step, the selection agent performs the chip selection again based on feedback content provided by the evaluation agent, namely the evaluation content corresponding to the current confidence level, thereby effectively improving accuracy of the chip selection.

For the steps SC1 to SC3 and the step SC4, the embodiments of the present disclosure design the evaluation agent through prompt engineering to implement the above LLM-based chip selection method, especially the step SC2 therein. The prompt engineering is divided into three parts: a task-specific prompt, an evaluation reference, and an evaluation precaution. The task-specific prompt is designed to enable the evaluation agent to understand its own confidence evaluation task. The evaluation reference includes examples and explanations of four levels of evaluation, and the evaluation precaution includes a requirement for a response from the evaluation agent, such that the evaluation agent can provide an accurate level evaluation and a basis.

Based on the above detailed descriptions of the interactive agent 31, the selection agent 32, and the evaluation agent 33, a basic principle of the LLM-based chip selection framework 30 in the embodiments of the present disclosure is as follows:

The interactive agent continuously interacts with the user, extracts a chip product requirement of the user after determining that the chip product requirement of the user is feasible, and sends a result to the selection agent. The selection agent performs comprehensive analysis based on the chip product requirement input by the interactive agent, and finally inputs a to-be-recommended chip product model and a related description into the evaluation agent as a result. The evaluation agent compares the chip product requirement extracted by the interactive agent with a to-be-recommended chip product provided by the selection agent, in order to determine whether the to-be-recommended chip product fully meets the user requirement, and provides an evaluated confidence level and a basis. If the confidence level evaluated by the evaluation agent is not the highest level, the basis provided by the evaluation agent is re-input into the selection agent, and the to-be-recommended chip product is changed accordingly. If the confidence level evaluated by the evaluation agent is the highest level, a final recommended chip product, along with a basis and relevant product description parameters, is input to the user.

Based on the aforementioned LLM-based chip selection framework 30, in the embodiments of the present disclosure, the interactive agent interacts with the user and extracts all interactive information during the interaction to obtain to-be-processed interactive information, performs requirement analysis on the to-be-processed interactive information, and outputs data required by the selection agent to perform the chip selection, that is, the requirement information. The selection agent, as the generation module, performs the chip selection based on the requirement information by combining the preset retrieval module, reranking module, and local knowledge base, thereby integrating an LLM and retrieval-augmented generation. In this way, a selection capability can be improved, and even when there are a plurality of similar chip products, an optimal solution can also be output. In addition, the evaluation agent also performs the confidence evaluation on the chip selection result of the selection agent, namely the recommendation information, thereby ensuring reliability of the recommendation information and meeting the user's expectation.

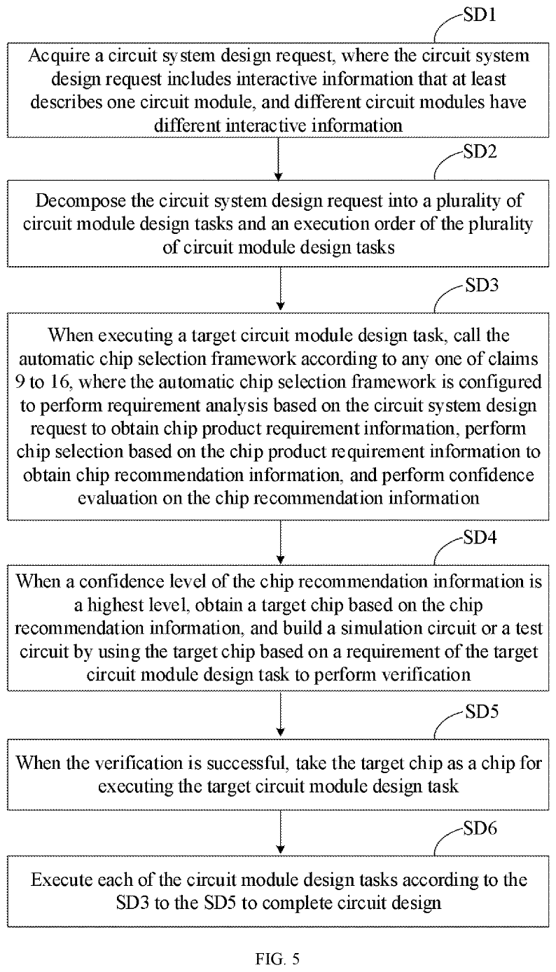

As shown in FIG. 5, the embodiments of the present disclosure further provide a circuit design method, including the following steps.
SD1: A circuit design request is acquired, where the circuit design request includes interactive information that at least describes one circuit module, and different circuit modules have different interactive information.
SD2: The circuit design request is decomposed into a plurality of circuit module design tasks and an execution order of the plurality of circuit module design tasks.
SD3: When a target circuit module design task is executed, the above chip selection framework is called, where the chip selection framework is configured to perform requirement analysis based on the circuit design request to obtain chip product requirement information, perform chip selection based on the chip product requirement information to obtain chip recommendation information, and perform confidence evaluation on the chip recommendation information.
SD4: When a confidence level of the chip recommendation information is a highest level, a target chip is obtained based on the chip recommendation information, and a simulation circuit or a test circuit is built by using the target chip based on a requirement of the target circuit module design task to perform verification.
SD5: When the verification is successful, the target chip is taken as a chip for executing the target circuit module design task.
SD6: Each of the circuit module design tasks is executed according to the SD3 to the SD5 to complete circuit design.

Through the steps SD1 to SD6, the embodiments of the present disclosure decompose the circuit design request and obtain all circuit modules required for completing the circuit design request, as well as a design sequence of each circuit module. Moreover, for each circuit module, the chip selection is performed through the aforementioned chip selection framework, which simplifies an existing board-level circuit design process and realizes automatic chip selection for each module of a circuit system, thereby improving design efficiency and accuracy of a board-level circuit.

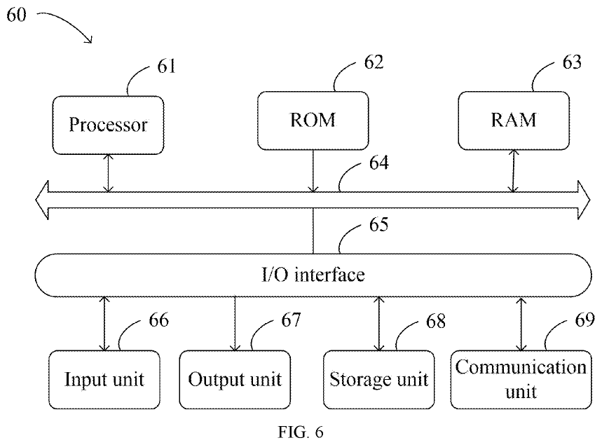

FIG. 6 is a schematic structural diagram of electronic device 60 configured to implement the LLM-based chip selection method and the circuit design method in the embodiments of the present disclosure. The electronic device is intended to represent various forms of digital computers, such as a laptop, a desktop computer, a workbench, a personal digital assistant, a server, a blade server, a mainframe computer, and other suitable computers. The electronic device can also represent various forms of mobile apparatuses, such as a personal digital assistant, a cellular phone, a smartphone, a wearable device (for example, a helmet, glasses, or a watch), and other similar computing apparatuses. The components, their connections and relationships, and their functions shown in this specification are only examples and are not intended to limit the implementation of the present disclosure described and/or required in this specification.

As shown in FIG. 6, the electronic device 60 includes at least one processor 61, and a memory communicatively connected to the at least one processor 61, for example, read-only memory (ROM) 62 and random access memory (RAM) 63. The memory stores a computer program executable on the at least one processor. The processor 61 can perform various suitable actions and processing according to the computer program stored in the ROM 62 or a computer program loaded from storage unit 68 to the RAM 63. The RAM 63 can also store various programs and data required for operations of the electronic device 60. The processor 61, the ROM 62, and the RAM 63 are connected to each other through bus 64. Input/output (I/O) interface 65 is also connected to the bus 64.

A plurality of components in the electronic device 60 are connected to the I/O interface 65, including: input unit 66 such as a keyboard and a mouse; output unit 67 such as various types of displays and speakers; the storage unit 68 such as a magnetic disk and an optical disk; and communication unit 69 such as a network card, a modem, and a wireless communication transceiver. The communication unit 69 allows the electronic device 60 to exchange information/data with another device by using a computer network such as the Internet and/or various telecommunication networks.

The processor 61 may be various general-purpose and/or special-purpose processing assemblies with processing and computing capabilities. Some examples of the processor 61 include, but are not limited to, a central processing unit (CPU), a graphics processing unit (GPU), various dedicated AI computing chips, various processors for running machine learning model algorithms, a digital signal processor (DSP), any appropriate processor, controller and microcontroller, and the like. The processor 61 performs various methods and processing described above, for example, an optimization method based on a gun-ball linkage surveillance system.

In some embodiments, a data processing method for chip selection may be implemented as a computer program, which is tangibly incorporated into a computer-readable storage medium, such as the storage unit 68. In some embodiments, the computer program may be partially or completely loaded into and/or installed on the electronic device 60 through the ROM 62 and/or the communication unit 69. When the computer program is loaded into the RAM 63 and executed by the processor 61, one or more steps of the data processing method described above can be performed. Alternatively, in other embodiments, the processor 61 may be configured to perform the data processing method by any other suitable means (for example, by means of firmware).

In this specification, the implementations of the above-described system and technology may be implemented in a digital electronic circuit system, an integrated circuit system, a field programmable gate array (FPGA), an application specific integrated circuit (ASIC), an application specific standard product (ASSP), a system on chip (SoC), a complex programmable logic device (CPLD), computer hardware, firmware, and software, and/or a combination thereof. These implementations may be implemented in at least one computer program. The at least one computer program may be executed and/or interpreted on a programmable system including at least one programmable processor. The programmable processor may be a special-purpose or general-purpose programmable processor, and can receive data and instructions from a storage system, at least one input apparatus, and at least one output apparatus, and transmit data and instructions to the storage system, the at least one input apparatus, and the at least one output apparatus.

Computer programs for implementing the methods of the present disclosure may be written in any combination of one or more programming languages. The computer programs can be provided for a processor of a general-purpose computer, a special-purpose computer, or any other programmable data processing apparatus, such that the computer programs are executed by the processor to implement functions/operations specified in the flowcharts and/or block diagrams. The computer programs may be executed fully on a machine, executed partially on a machine, executed partially on a machine as an independent software package and partially on a remote machine, or executed fully on a remote machine or server.

In the context of the present disclosure, the computer-readable storage medium may be a tangible medium that may contain or store a computer program used by or used in combination with an instruction execution system, apparatus or device. The computer-readable storage medium may be, but is not limited to, an electronic, magnetic, optical, electromagnetic, infrared, or semiconductor system, apparatus or device, or any combination thereof. Alternatively, the computer-readable storage medium may be a machine-readable signal medium. More specific examples of the machine-readable storage medium include: an electrical connection with one or more wires, a portable computer disk, a hard disk, a RAM, a ROM, an erasable programmable read-only memory (an EPROM or a flash memory), an optical fiber, a portable compact disc read-only memory (CD-ROM), an optical storage device, a magnetic storage device, or any suitable combination thereof.

In order to provide interaction with a user, the system and technology described herein can be implemented on an electronic device. The electronic device is equipped with a display apparatus (for example, a cathode ray tube (CRT) or a liquid crystal display (LCD) monitor) for displaying information to the user; and a keyboard and a pointing apparatus (such as a mouse or a trackball), which can be used by the user to provide an input to the electronic device. Other types of apparatuses can also be used to provide the interaction with the user. For example, a feedback provided to the user may be any form of sensory feedback (such as a visual feedback, an auditory feedback, or a tactile feedback). In addition, the input from the user can be received in any form (including a sound input, a speech input, or a tactile input).

The system and technology described herein can be implemented in a computing system including a backend component (for example, as a data server), a computing system including a middleware component (such as an application server), a computing system including a frontend component (such as a user computer with a graphical user interface or a web browser, where through the graphical user interface or the web browser, the user can interact with the implementations of the system and technology described herein), or a computing system including any combination of such a backend component, a middleware component, or a frontend component. The components of the system can be interconnected through digital data communication of any form or medium (such as a communication network). For example, the communication network includes a local area network (LAN), a wide area network (WAN), a blockchain network, and the Internet.

The computing system may include a client and a server. The client and the server are generally far apart from each other and typically interact through the communication network. A relationship between the client and the server is generated by running computer programs that have a client-server relationship with each other on a corresponding computer. The server may be a cloud server, which is also known as a cloud computing server or a cloud host, and is a type of host product in a cloud computing service system.

Finally, it should be noted that the embodiments above are merely intended to explain, rather than to limit, the technical solutions of the present disclosure. Although the present disclosure is described in detail with reference to the preferred embodiments, those of ordinary skill in the art should understand that modifications or equivalent substitutions may be made to the technical solutions of the present disclosure without departing from the spirit and scope of the technical solutions of the present disclosure, and these modifications or equivalent substitutions shall fall within the scope of the claims of the present disclosure.

1. A large language model (LLM)-based chip selection method, comprising:
SA1, acquiring to-be-processed interactive information, wherein the to-be-processed interactive information is all interactive information generated during chip selection in a human-machine collaborative mode;
SA2, performing information extraction on the to-be-processed interactive information, and obtaining initial requirement information;
SA3, analyzing whether the initial requirement information comprises an abnormal requirement, wherein the abnormal requirement indicates that the initial requirement information has at least one of an unreasonable requirement expression, an ambiguous expression, and an irrelevant expression;
SA4, if the initial requirement information comprises the abnormal requirement, feeding the abnormal requirement and a cause of the abnormal requirement back to a user, and interacting with the user to re-generate interactive information, so as to perform the SA2 based on newly generated interactive information; and
SA5, if the initial requirement information does not comprise the abnormal requirement, performing requirement analysis and standardization processing based on the initial requirement information, thereby obtaining, based on the initial requirement information, chip product requirement information whose data item name at least comprises product classification, and outputting the chip product requirement information;
wherein supervised fine-tuning training is performed on a first basic agent by using a first hybrid dataset comprising a proper noun dataset, a product classification dataset, a multi-turn dialogue dataset, and a general dataset, and an interactive agent is obtained to perform the SA1 to the SA5;
wherein the product classification dataset comprises N category data contents based on M first-level chip categories; and
if an n^{th} category data content belongs to an m^{th} first-level chip category, the n^{th} category data content comprises a product classification question-answer (QA) pair constituted by a second-level chip category subordinate to the m^{th} first-level chip category and a question sentence based on the second-level chip category subordinate to the m^{th} first-level chip category, and a system prompt based on the product classification QA pair;
wherein M and N are positive integers, n is a positive integer less than or equal to N, and m is a positive integer less than or equal to M.

2. The LLM-based chip selection method according to claim 1, wherein the proper noun dataset comprises K noun data contents based on K proper nouns; and
a k^{th} noun data content comprises a proper noun QA pair constituted by a correct interpretation of a k^{th} proper noun and a question sentence based on the correct interpretation of the k^{th} proper noun, and a system prompt based on the proper noun QA pair;
wherein k is a positive integer less than or equal to K, and K is a positive integer.

3. The LLM-based chip selection method according to claim 1, wherein the multi-turn dialogue dataset comprises U multi-turn dialogue data contents based on L multi-turn dialogues; and
if a u^{th} multi-turn dialogue data content belongs to an l^{th} multi-turn dialogue, the u^{th} multi-turn dialogue data content comprises a multi-turn dialogue QA pair constituted by a simulated question in the l^{th} multi-turn dialogue and a reply content based on the simulated question in the l^{th} multi-turn dialogue, a system prompt based on the multi-turn dialogue QA pair, and a historical dialogue set;
wherein L and U are positive integers, l is a positive integer less than or equal to L, and u is a positive integer less than or equal to U; in the l^{th} multi-turn dialogue, the simulated question is generated by simulating a user question about a randomly selected chip product manual; and the reply content based on the simulated question in the l^{th} multi-turn dialogue is generated based on the randomly selected chip product manual.

4. The LLM-based chip selection method according to claim 3, wherein in the 1th multi-turn dialogue, the simulated question is also randomly selected from a preset question database; and for the simulated question randomly selected from the preset question database, the reply content of the simulated question comprises content of the randomly selected chip product manual; and
the preset question database comprises a plurality of preset questions, and each of the plurality of preset questions comprises at least one of the unreasonable requirement expression, the ambiguous expression, and the irrelevant expression.

5. An LLM-based chip selection method, applied to an interactive agent, wherein the interactive agent executes the LLM-based chip selection method according to any one of claims 1 to 4, and comprises:
SB1, acquiring chip product requirement information provided by the interactive agent; and
SB2, performing, by a selection agent as a generation module, chip selection based on the chip product requirement information by combining a pre-configured retrieval module, a reranking module, and a local knowledge base, and outputting chip recommendation information; wherein
the SB2 comprises:
comparing the chip product requirement information with chip product data stored in the local knowledge base by using the retrieval module, obtaining a plurality of relevant documents, and sending the plurality of relevant documents to the reranking module;
performing relevance ranking on the plurality of relevant documents by using the reranking module, and sending a ranking result to the selection agent, wherein in the ranking result, a relevant document with higher relevance is assigned a smaller serial number, and a relevant document whose serial number is smaller than a preset serial number is a strongly-related document; and
analyzing all strongly-related documents based on the chip product requirement information, and outputting the chip recommendation information.

6. The LLM-based chip selection method according to claim 5, comprising: constructing a retrieval triplet dataset to perform supervised contrastive learning training on a basic embedding model, and obtaining the retrieval module upon completion of the training;
wherein the constructed retrieval triplet dataset comprises a query retrieval element, a positive-sample retrieval element, and a negative-sample retrieval element; the query retrieval element is extracted from total requirement information data; the positive-sample retrieval element is unique chip product data selected from the local knowledge base to reply to the query retrieval element; and the negative-sample retrieval element is a plurality of pieces of chip product data randomly extracted from the local knowledge base.

7. The LLM-based chip selection method according to claim 5, comprising: constructing a reranking triplet dataset to perform supervised contrastive learning training on a basic reranking model, and obtaining the reranking module upon completion of the training;
wherein the constructed reranking triplet dataset comprises a query reranking element, a positive-sample reranking element, and a negative-sample reranking element; the query reranking element is a simulated requirement description whose data size is less than a preset quantity of bytes; the positive-sample reranking element is a unique correct answer compiled based on the simulated requirement description; and the negative-sample reranking element is a plurality of wrong answers compiled based on the simulated requirement description, wherein a similarity between each of the plurality of wrong answers and the unique correct answer is greater than a preset similarity.

8. The LLM-based chip selection method according to claim 5, wherein any piece of chip product data stored in the local knowledge base comprises a document description of a product feature, a document description of a product application case, a document description of a key parameter, and a document description of complete information.

9. The LLM-based chip selection method according to claim 5, comprising: performing two-stage training comprising continued pre-training and supervised fine-tuning training on a second basic agent, and obtaining the selection agent to perform the SB1 and the SB2; wherein
in the continued pre-training, multi-dimensional chip text data is obtained, text preprocessing is performed on the multi-dimensional chip text data to obtain a plurality of corpus blocks, and the second basic agent is trained by using the plurality of corpus blocks; and
in the supervised fine-tuning training, the second basic agent after the continued pre-training is trained by using a second hybrid dataset comprising a proper noun dataset, a product classification dataset, a chip selection dataset, and a general dataset, and the selection agent is obtained.

10. The LLM-based chip selection method according to claim 9, wherein the chip selection dataset comprises P pieces of chip matching data; and
a p^{th} piece of chip matching data comprises a chip matching QA pair constituted by a simulated chip requirement description and recommendation information meeting the simulated chip requirement description, and a system prompt based on the chip matching QA pair;
wherein p is a positive integer less than or equal to P, P is a positive integer, and the simulated chip requirement description is generated based on a randomly selected chip product manual; and
the recommendation information meeting the simulated chip requirement description comprises a chip product model and a chip product description that are recorded in the randomly selected chip product manual.

11. An LLM-based chip selection system, comprising an LLM-driven interactive agent, a selection agent, and an evaluation agent, wherein the interactive agent executes the LLM-based chip selection method according to any one of claims 1 to 4; the selection agent executes the LLM-based chip selection method according to any one of claims 5 to 10; and the evaluation agent performs following steps:
SC1, acquiring chip recommendation information;
wherein the chip recommendation information is a result of performing, by the selection agent as a generation module, chip selection based on chip product requirement information by combining a pre-configured retrieval module, a reranking module, and a local knowledge base;
SC2, performing confidence evaluation on the chip recommendation information; and
SC3, if a confidence level obtained according to the SC2 is a highest level, sending the chip recommendation information to a user.

12. The chip selection system according to claim 11, wherein the SC2 comprises:
when performing the confidence evaluation on the chip recommendation information, further generating evaluation content.

13. The chip selection system according to claim 12, further comprising:
SC4, if the confidence level obtained according to the SC2 is not the highest level, sending evaluation content corresponding to the confidence level obtained according to the SC2 to the selection agent, such that the selection agent modifies the chip recommendation information.

14. The chip selection system according to claim 11, wherein the evaluation agent is designed through prompt engineering, and the SC1 to the SC3 are performed by the evaluation agent.

15. A circuit design method, comprising:
SD1, acquiring a circuit design request, wherein the circuit design request comprises interactive information that at least describes one circuit module, and different circuit modules have different interactive information;
SD2, decomposing the circuit design request into a plurality of circuit module design tasks and an execution order of the plurality of circuit module design tasks;
SD3, when executing a target circuit module design task, calling the chip selection system according to any one of claims 11 to 14, wherein the chip selection system is configured to perform requirement analysis based on the circuit design request to obtain chip product requirement information, perform chip selection based on the chip product requirement information to obtain chip recommendation information, and perform confidence evaluation on the chip recommendation information;
SD4, when a confidence level of the chip recommendation information is a highest level, obtaining a target chip based on the chip recommendation information, and building a simulation circuit or a test circuit by using the target chip based on a requirement of the target circuit module design task to perform verification;
SD5, when the verification is successful, taking the target chip as a chip for executing the target circuit module design task; and
SD6, executing each of the circuit module design tasks according to the SD3 to the SD5 to complete circuit design.

16. An electronic device, comprising a memory, a processor, and a computer program stored in the memory and executable on the processor, wherein the processor executes the computer program to implement the LLM-based chip selection method according to any one of claims 1 to 4, the LLM-based chip selection method according to any one of claims 5 to 10, or the circuit design method according to claim 15.

17. A computer-readable storage medium, storing a computer program thereon, wherein the computer program is executed by a processor to implement the LLM-based chip selection method according to any one of claims 1 to 4, the LLM-based chip selection method according to any one of claims 5 to 10, or the circuit design method according to claim 15.

18. A computer program product, comprising a computer program, wherein the computer program is executed by a processor to implement the LLM-based chip selection method according to any one of claims 1 to 4, the LLM-based chip selection method according to any one of claims 5 to 10, or the circuit design method according to claim 15.
